(19) United States
(12) Patent Application Publication
(10) Pub. No.: US 2002/0062553 A1
(43) Pub. Date: May 30, 2002

(54) Surface mounting device and method thereof

(75) Inventors: Ji Hyun Hwang, Kyungki-do (KR); Do Hyun Kim, Kyoungki-do (KR)

Correspondence Address: FLESHNER & KIM, LLP, P.O. Box 221200, Chantilly, VA, 20153-1200, US

(73) Assignee: Mirae Corporation

(21) Appl. No.: 09/987,421

(22) Filed: Nov. 14, 2001

(30) Foreign Application Priority Data
Nov. 24, 2000 (KR) 2000-70454
Nov. 24, 2000 (KR) 2000-70455

(51) Int. Cl. H05K 3/30; B23P 19/00

(52) U.S. Cl. 29/832; 29/739; 29/742

(57) ABSTRACT

A surface mounting device comprising: multiple transfers being moved in the X and Y axis directions by an X-Y gantry installed on a base frame and supplying a printed circuit board(PCB) for mounting parts or loading the discharged PCB by a head unit for sucking parts supplied from a parts supply unit and mounting the sucked parts on the PCB and multiple conveyers installed to be moved horizontally in a predetermined direction at a predetermined position on the base frame for carrying the PCB supplied from the multiple transfers to a parts mounting work position and discharging the same to the multiple transfers when the mounting of the parts is finished.

### BACKGROUND OF THE INVENTION

1. Field of the Invention

The present invention relates to a surface mounting device and method thereof, and more particularly, to a surface mounting device and method thereof for enhancing a parts mounting speed by improving a speed for supplying a printed circuit board to a parts mounting work position or for discharging the printed circuit board on which parts have been mounted.

2. Description of the Related Art

The construction of a conventional surface mounting device will now be described with reference to FIGS. 1 and 2. FIG. 1 is a perspective view of a conventional surface mounting device. FIG. 2 is a plane view of a surface mounting device schematically illustrating the internal construction of the surface mounting device as shown in FIG. 1. As illustrated therein, the surface mounting device includes a base frame 1, X and Y gantries 2 and 3, a conveyer 4, a parts supply unit 5, and a head unit 6.

The head unit 6 is driven in the X-axis direction by an X-axis motor 2a and an X-axis ball screw 2b and in the Y-axis direction by a Y-axis motor 3a and a Y-axis ball screw 3b each installed at the X and Y gantries 2 and 3 installed on the top surface of the base frame 1, for thereby vacuum sucking parts supplied from the parts supply unit 5 and mounting them on the printed circuit board (P). The printed circuit board (P) on which parts are mounted is carried to the conveyer 4 installed on the base frame 1 through a printed circuit board inlet 4a and then is carried to a parts mounting work position by the conveyer 4.

Afterwards, when parts has been mounted by the head unit 6, the printed circuit board (P) is discharged through a printed circuit board outlet 4b by the conveyer 4 in the stop state. Here, the parts mounted on the printed circuit board (P) are supplied by a tape feeder 5a installed at the parts supply unit 5. The tape feeder 5a is installed by moving a tape wheel 5b containing parts by a wheel moving device 5c. When the tape wheel 5b is installed at the tape feeder 5a, the tape feeder 5a supplies parts at a predetermined pitch so that the head unit 6 can continuously vacuum suck the parts contained in the tape wheel 5b and can mount them on the printed circuit board (P).

As described above, in a case in which the printed circuit board is sequentially carried to the parts mounting position one by one by the conveyer and then is discharged as the parts are mounted on the printed circuit board carried to the parts mounting position by the head unit, the supply and discharge speed of the printed circuit board is decreased, thereby degrading the productivity of a parts mounting work of the surface mounting device.

### SUMMARY OF THE INVENTION

It is, therefore, an object of the present invention to provide a surface mounting device and method thereof in which a printed circuit board is carried to a parts mounting work position by moving a plurality of conveyers horizontally to a predetermined direction at a base frame for thereby eliminating a feed delay of the printed circuit board caused by the operation of mounting parts on the printed circuit board.

It is another object of the present invention to provided a surface mounting device and method thereof in which a printed circuit board is carried to a parts mounting work position by moving a plurality of conveyers horizontally to a predetermined direction at a base frame or moving in plane motion in a predetermined direction a plurality of transfer units for supplying the printed circuit board to the plurality of transfer units or loading the discharged printed circuit board, for thereby eliminating a feed delay of the printed circuit board caused by the operation of mounting parts on the printed circuit board.

It is another object of the present invention to provided a surface mounting device and method thereof which has a plurality of transfers capable of moving in plane motion and a plurality of conveyers capable of moving in horizontal motion, for thereby eliminating a feed delay of the printed circuit board caused by the operation of mounting parts on the printed circuit board, improving the feed speed of the printed circuit board, and accordingly enhancing the speed of mounting parts.

To achieve the above object, there is provided a surface mounting device comprising: a plurality of transfers being moved in the X and Y axis directions by an X-Y gantry installed on a base frame and supplying a printed circuit board for mounting parts or loading a discharged printed circuit by a head unit for sucking parts supplied from a parts supply unit and mounting the sucked parts on a printed circuit board; and a plurality of conveyers and being installed to be moved horizontally in a predetermined direction at a predetermined position on the base frame and carrying the printed circuit board supplied from the plurality of transfers to a parts mounting work position and discharging the same to the plurality of transfers when the mounting of the parts is finished.

Also, there is provided a surface mounting method comprising the steps of: carrying a printed circuit board loaded on the first transfer to a first conveyer unit by control of a controller; carrying the carried printed circuit board to a second conveyer unit by control of the controller when the printed circuit board is carried to the first conveyer unit; mounting parts on the printed circuit board carried to the second conveyer unit by control of the controller and carrying the printed circuit board loaded on the first transfer to the first conveyer unit when the printed circuit board is carried to the second conveyer unit; and discharging the printed circuit board on which parts have been mounted to the second transfer by control of the controller and carrying the printed circuit board carried to the first conveyer unit when the mounting of parts on the printed circuit board in the second conveyer unit is finished.

### BRIEF DESCRIPTION OF THE DRAWINGS

The above objects, features and advantages of the present invention will become more apparent from the following detailed description when taken in conjunction with the accompanying drawings, in which:

FIG. 1 is a perspective view of a surface mounting device according to the conventional art;

FIG. 2 is a plane view of a surface mounting device schematically showing the internal construction of the surface mounting device as illustrated in FIG. 1;

FIG. 3 is a plane view of a surface mounting device according to a first embodiment of the present invention;

FIG. 4 is a perspective view of the surface mounting device as illustrated in FIG. 3;

FIG. 5 is a plane view of a surface mounting device according to a second embodiment of the present invention;

FIG. 6 is a perspective view of the surface mounting device as illustrated in FIG. 5;

FIG. 7 is a view illustrating a parts mounting method using the surface mounting device according to the first embodiment of the present invention; and

FIGS. 8a through 8c are views illustrating the parts mounting method using the surface mounting device according to the second embodiment of the present invention.

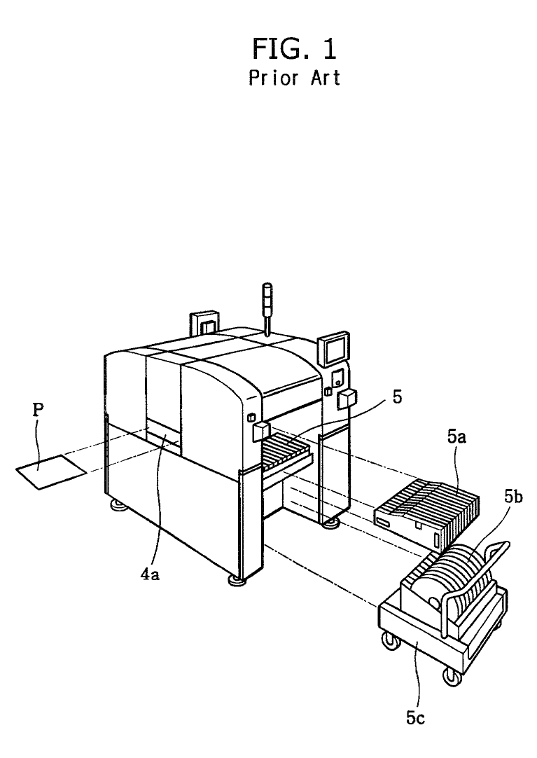

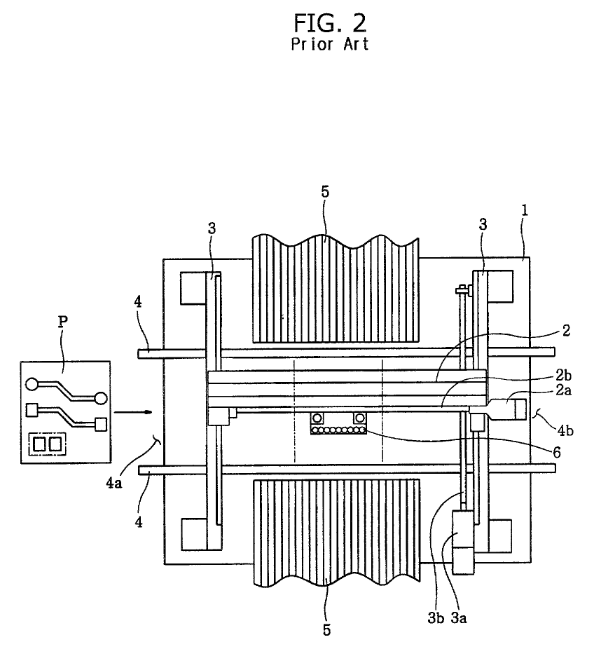

### DETAILED DESCRIPTION OF THE PREFERRED EMBODIMENT

A preferred embodiment of the present invention will now be described with reference to the accompanying drawings.

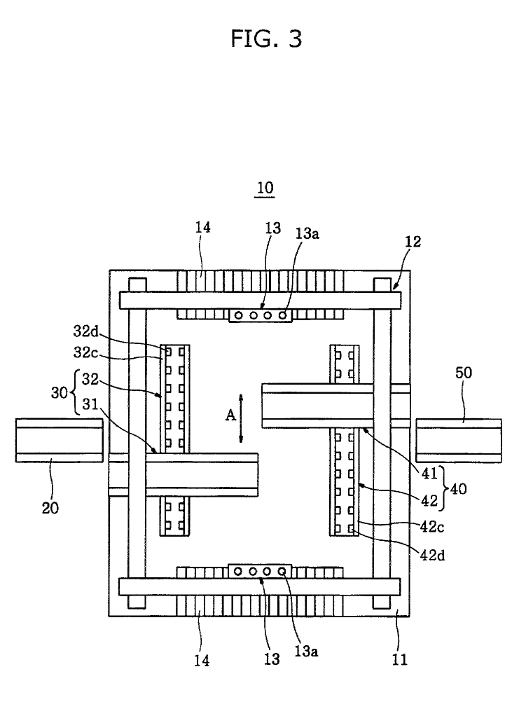

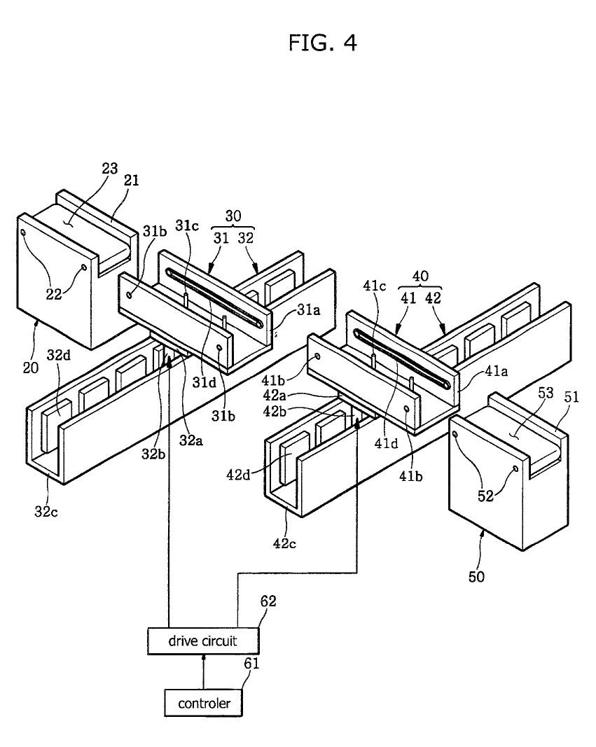

FIG. 3 plane view of a surface mounting device according to a first embodiment of the present invention. FIG. 4 is a perspective view of the surface mounting device as illustrated in FIG. 3. As illustrated therein, the surface mounting device includes: a plurality of transfers 20 and 50 being moved in the X and Y axis directions by an X-Y gantry 12 installed on a base frame 11 and supplying a printed circuit board for mounting parts or loading a discharged printed circuit by a head unit 13 for sucking parts supplied from a parts supply unit 14 and mounting the sucked parts on a printed circuit board (not shown); and a plurality of conveyers 30 and 40 being installed to be moved horizontally in a predetermined direction at a predetermined position on the base frame 11 and carrying the printed circuit board supplied from the plurality of transfers 20 and 50 to a parts mounting work position and discharging the same to the plurality of transfers 20 and 50 when the mounting of the parts is finished.

To explain the construction and operation of the surface mounting device 10 of the present invention, firstly, the construction and operation of the surface mounting device 10 according to first and second embodiments of the present invention will be explained, and then a parts mounting method using the surface mounting device 10 according to the first and second embodiments will be explained.

As illustrated in FIG. 3, the surface mounting device 10 of the present invention is constructed in such a manner that the X-Y gantry 12, the head unit 13, the part supply unit 14 and the plurality of conveyers 30 and 40 are installed on the base frame 11 and the plurality of transfers 20 and 50 are installed at both ends of the plurality of conveyers 30 and 40. Since the construction and operation of the X-Y gantry 12 installed on the base frame 11, the head unit 13 provided with a plurality of heads 13a and the parts supply unit 14 are identical to those according to the conventional art, so a detailed description thereof will be omitted. Now, the construction and operation of the present invention will be explained laying stress on the plurality of conveyers 30 and 40 for carrying or discharging the printed circuit board (P) to a parts mounting position (a position of the printed circuit board at which the head unit 13 mounts parts) and the plurality of transfers 20 and 50.

The plurality of transfers 20 and 50 are installed at both ends of the base frame 11 thus to supply the printed circuit board for mounting parts by the head unit 13 or load the discharged printed circuit board. The printed circuit board supplied from the plurality of transfers 20 and 50 is carried to a parts mounting work position from the plurality of conveyer units 30 and 40 installed to be moved horizontally in a predetermined direction at a predetermined position of the base frame 11, and is discharged to the plurality of transfers 20 and 50 when the mounting of the parts is finished.

To supply the printed circuit board to the plurality of conveyer units 30 and 40 or load the printed circuit board discharged from the plurality of conveyer units 30 and 40, the plurality of transfers 20 and 50 includes a first transfer 20 and a second transfer 50. The first transfer 20 is installed at one end of the base frame 11 at which the plurality of conveyer are installed to be moved horizontally in a predetermined direction and supplies the printed circuit board to the plurality of conveyer units 30 and 40. The second transfer 50 is installed at one end of the base frame 11 at which the plurality of conveyer units 30 and 40 are installed to be moved horizontally in a predetermined direction and loads the printed circuit board discharged from the plurality of conveyer units 30 and 40 to the outside of the surface mounting device 10.

To supply or discharge the printed circuit board, as shown in FIG. 4, the first and second transfers 20 and 50 each include transfer guide frames 21 and 51, a plurality of transfer rollers 22 and 52, and belt members 23 and 53. The transfer guide frames 21 and 51 guide the printed circuit board when supplying the printed circuit board to the plurality of conveyer units 30 and 40 in a state that the printed circuit board for mounting parts is loaded. The plurality of transfer rollers 22 and 52 are installed at a predetermined interval from each other at side walls of the transfer guide frames 21 and 51, and the belt members 23 and 53 for placing the printed circuit board are installed between the plurality of transfer rollers 22 and 52.

The plurality of transfer rollers 22 and 52 are connected to a rotating motor (not shown), are rotated by receiving the rotation force generated from the rotating motor, and thusly drives the belt members 23 and 53. The belt members 23 and 53 are driven by the rotation of the plurality of transfer rollers 22 and 52 to thus supply the printed circuit board to the plurality of conveyer units 30 and 40 or load the printed circuit board discharged from the plurality of conveyer units 30 and 40. The plurality of conveyer units 30 and 40 includes a first conveyer unit 30 and a second conveyer unit 40, which receive the supplied printed circuit board by driving the belt members 23 and 53 or discharge the printed circuit board to the belt members 23 and 53.

The first conveyer unit 30 is installed to be moved horizontally in a predetermined direction at a predetermined position of the base frame 11 and carries the printed circuit board supplied from the first transfer 20. The second conveyer unit 40 is installed to be moved horizontally in a predetermined direction at a predetermined position of the base frame 11 and discharges the printed circuit board carried from the first conveyer unit 30 to the second transfer 50. In this way, by making the first and second conveyer units 30 and 40 separately constructed and making them moved horizontally in a predetermined direction, each of them can be driven independently.

The first conveyer unit 30 that can be driven independently includes a first conveyer 31 and a first horizontal driving device 32, and the second conveyer unit 40 includes a second conveyer 41 and a second horizontal driving unit 42. The first conveyer 31 has the first horizontal driving unit 32 installed on the bottom thereof to carry the printed circuit board supplied from the first transfer 20, is installed at a predetermined position of the base frame 11, is moved horizontally in a predetermined direction by the first horizontal driving unit 32 and then is arranged in the width of the first transfer 20. The printed circuit board arranged in the width of the first transfer 20 and carried to the first conveyer 31 is carried to the second conveyer 41.

The second conveyer 41 discharges the printed circuit board carried from the first conveyer 31 to the second transfer 50. To discharge the printed circuit board carried from the first conveyer 31 to the second transfer 50, the second conveyer 41 is arranged in the width of the first conveyer 31 and the second transfer 50. For this, the second conveyer 41 has a second horizontal driving device 42 installed on the bottom of thereof, is installed at a predetermined position of the base frame 11, and is moved horizontally in a predetermined direction. The first and second conveyers 31 and 41 moved horizontally for receiving the printed circuit board each include conveyer guide frames 31a and 41a, conveyer width adjusting rollers 31b and 41b, conveyer lifting members 31c and 41c and conveyer driving units 31d and 41d.

The conveyer width adjusting rollers 31b and 41b are installed at a predetermined position of the conveyer guide frames 31a and 41a, the conveyer lifting members 31c and 41c are installed on the bottom of the inside thereof, and the conveyer driving units 31d and 41d are installed at an inner sidewall thereof. The conveyer guide frames 31a and 41a guide the carried printed circuit board, and the conveyer width adjusting rollers 31b and 41b are used for guiding the conveyer guide frames 31a and 41a when adjusting the width of the conveyer guide frames 31a and 41a according to the width of the printed circuit board. In case of mounting parts on the printed circuit board, the conveyer lifting members 31c and 41c lift/lower the printed circuit board at a predetermined height so that the head unit 13 can mount the parts. To mount parts, the conveyer driving units 31d and 41d generate the driving force for carrying the printed circuit board lifted/lowered to the predetermined height. By this driving force, the printed circuit board is moved along the conveyer guide frames 31a and 41a.

To receive the printed circuit board being moved along the conveyer guide frames 31a and 41a, the first horizontal driving device 32 and the second horizontal driving device 42 are installed respectively at the bottom of the conveyer guide frames 31a and 41a. As the first and second driving devices 32 and 42, a linear motor is used, which consists of movers 32a and 42a provided with armature coils 32b and 42b and stators 32c and 42c having a plurality of permanent magnets 32d and 42d arranged therein. The linear motor horizontally moves the conveyer guide frames 31a and 41a in a predetermined direction according to an electric signal supplied from a drive circuit 62 by control of a controller 61c and arranges the same in the width of the first transfer 20 and the second transfer 50. Here, the linear motor is one of a coil mover linear motor and a permanent magnet mover linear motor (not shown). Besides the linear motor, a ball screw driving device (not shown) or a timing belt driving unit (not shown) can be selected.

In this way, as the first and second conveyers 31 and 41 can be moved in a horizontal direction independently without mutual interference by using the first and second horizontal driving devices 32 and 42, one of the first and second conveyers 31 and 41 can mount parts while the other exchanges the printed circuit board with the first and second transfer 20 and 50, for thereby reducing a parts mounting time.

A second embodiment of the present invention for reducing a time for mounting parts on the printed circuit board using the surface mounting device 10 will now be explained with reference to the accompanying drawings.

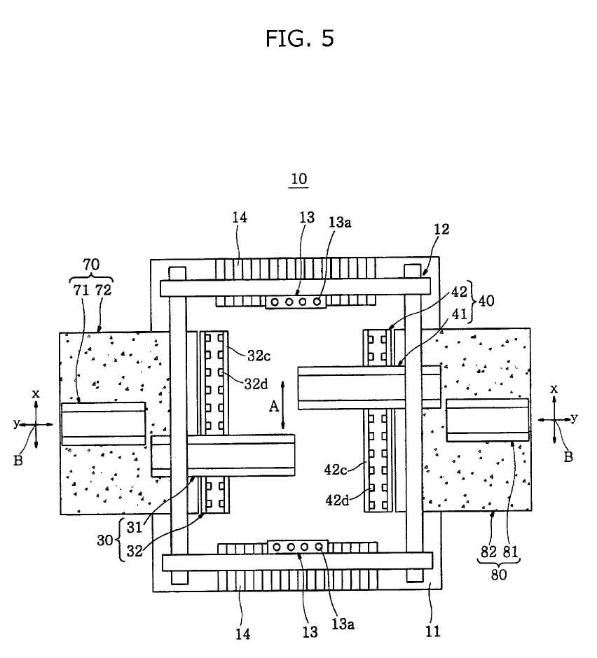

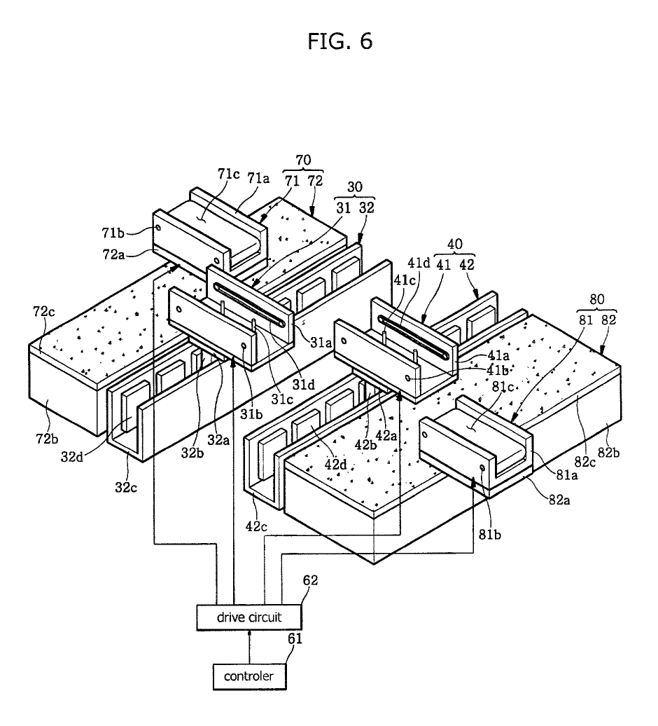

FIG. 5 is a plane view of a surface mounting device according to a second embodiment of the present invention. FIG. 6 is a perspective view of the surface mounting device as illustrated in FIG. 5. As illustrated therein, the surface mounting device includes: a plurality of plane motion transfer units 70 and 80 being moved in the X and Y axis directions by an X-Y gantry 12 installed on a base frame 11 and loading a printed circuit board moved in plane motion in a predetermine direction in order to supply or discharge the printed circuit board for mounting parts by a head unit 13 for sucking parts supplied from a parts supply unit 14 and mounting the sucked parts on the printed circuit board; and a plurality of conveyer units 30 and 40 being installed to be moved horizontally in a predetermined direction at a predetermined position of the base frame 11 and carrying the printed circuit board supplied from the plurality of plane motion transfer units 70 and 80 to a parts mounting work position and discharging the same to the plurality of plane motion transfer units 70 and 80 when the mounting of the parts is finished.

In the construction of the second embodiment of the present invention, the construction of the other elements excepting the plurality of plane motion transfer units 70 and 80 is the same as the construction and operation of the surface mounting device 10 as shown in FIGS. 3 and 4. For example, the construction and operation of the plurality of conveyer 30 and 40 as shown in FIGS. 5 and 6 are identical to those of the plurality of conveyers 30 and 40 as shown in FIGS. 3 and 4, so a detailed description thereof will be omitted.

The plurality of plane motion transfer units 70 and 80 are moved in plane motion in a predetermined direction as shown in arrow B of FIG. 5 in order to supply or discharge the printed circuit board for mounting parts. To transfer parts to the first and second conveyer units 30 and 40 in plane motion in a predetermined direction, the plurality of plane motion transfer units 70 and 80 includes a first plane motion transfer unit 70 supplying the printed circuit board to the plurality of conveyer units 30 and 40 and a second plane motion transfer unit 80 loading the printed circuit board discharged from the plurality of conveyer units 30 and 40.

The first plane motion transfer unit 70 includes a first plane motion transfer 71 carrying the printed circuit board and a first plane driving device 72 moving the first plane motion transfer 71 in plane motion in a predetermined direction. The second plane motion transfer unit 80 includes a second plane motion transfer 81 carrying the printed circuit board and a second plane driving device 82 moving the second plane motion transfer 81 in plane motion in a predetermined direction.

In this construction, the operation of transfer guide frames 71 and 81a, a plurality of transfer rollers 71b and 81b and belt members 71c and 81c, respectively, constituting the first and second plane motion transfers 71 and 81 is identical to that of the transfer guide frames 21 and 51, the plurality of transfer rollers 22 and 52 and the belt members 23 and 53 as shown in FIG. 4, so a detailed description thereof will be omitted.

To move in plane motion the first and second plane motion transfers 71 and 81 each provided with the transfer guide frame 71a and 81a, the plurality of transfer rollers 71b and 81b and the belt member 71c and 81c, the first plane driving device 72 and the second plane driving device 82 are installed on the bottom of the first plane motion transfer 71 and the second plane motion transfer 72. Here, the first and second plane driving devices 72 and 82 each is constructed as a plane motor for moving the first and second plane motion transfers 71 and 81 in plane motion.

The first and second plane motion transfers 71 and 81 constructed as the linear motor each includes armature frames 72a and 82a adapted for an armature coil portion (not shown) and permanent magnet frames 72b and 82b provided with permanent magnets 72c and 82c. The armature frames 72a and 82a are installed at the bottom of the first plane motion transfer 71 and the second plane motion transfer 81. When an electric signal outputted from a drive circuit 62 is supplied by control of a controller 61, a thrust force is generated between the permanent magnet frames 72b and 82b installed on the bottom of the armature frames 72a and 82a. By this thrust force, the first plane motion transfer 71 and the second plane motion transfer 81 are moved in plane motion along with the surface of the permanent magnet frames 72b and 82b.

The permanent magnet frames 72b and 82b providing the plane motion passage of the first and second plane motion transfers 71 and 81 are installed even at a position adjacent to the first and second plane driving devices 32 and 42 disposed inside the base frame 11 so that the first and second plane motion transfers 71 and 81 are arranged respectively with one end of the first and second conveyer units 30 and 40. In this way, as the first and second plane motion transfers 71 and 81 can move even to the position adjacent to the first and second conveyer units 30 and 40, the first plane motion transfer 71 can directly transfer the printed circuit board to the first and second conveyers 30 and 40 in turns and the second plane motion transfer 81 can directly receive the printed circuit board discharged from the first and second conveyers 30 and 40 in turns.

As the first plane motion transfer 71 and the second plane motion transfer 81 can supply or receive the printed circuit board to/from the first conveyer unit 30 and the second conveyer unit 40 in turns, the feed speed of the printed circuit board can be improved and the printed circuit board can be carried in various passages, for thereby enhancing the parts mounting work speed.

A parts surface mounting method using the surface mounting device according to the first and second embodiments of the present invention will now be explained with reference to the accompanying drawings.

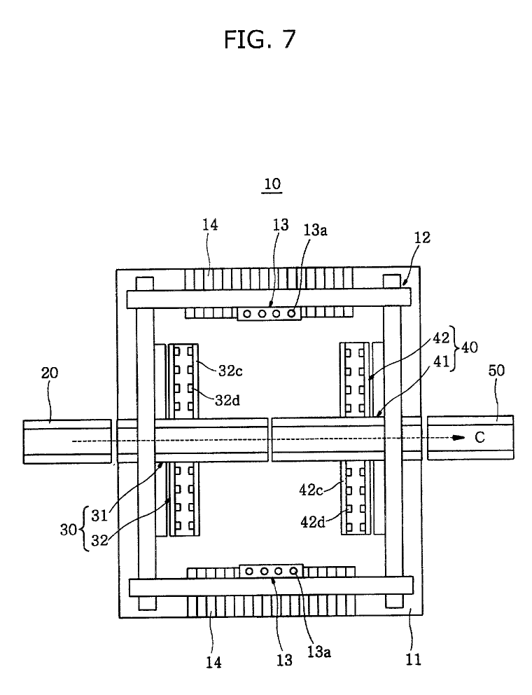

FIG. 7 is a view illustrating a parts mounting method using the surface mounting device according to the first embodiment of the present invention. As illustrated therein, firstly, the step of carrying a printed circuit board loaded on the first transfer 20 to the first conveyer unit 30 by control of the controller 61 is performed. When the printed circuit board is carried to the first conveyer unit 30, the step of carrying the carried printed circuit board to the second conveyer unit 40 by control of the controller 61 is performed. When the printed circuit board is carried to the second conveyer unit 40, the step of mounting parts on the printed circuit board carried to the second conveyer unit 40 by control of the controller 61 and carrying the printed circuit board loaded on the first transfer 20 to the first conveyer unit 30 is performed.

In the above step, it is also possible to mount parts on the printed circuit board carried to the first conveyer unit 30 by control of the controller 61 and then carry the printed circuit board to the second conveyer unit 40. Here, the step of mounting parts on the printed circuit board is performed by the head unit 13 driven by receiving a driving signal outputted from the drive circuit 62 by control of the controller 61.

When the mounting of parts on the printed circuit board in the second conveyer unit 40 is finished, the step of discharging the printed circuit board on which parts have been mounted to the second transfer 50 by control of the controller 61 and carrying the printed circuit board carried to the first conveyer unit 30 is performed, for thereby carrying the printed circuit board in the direction as shown in arrow C of FIG. 7 and mounting parts on the printed circuit board. Here, when parts have been mounted on the printed circuit board carried to the second conveyer unit 40, the printed circuit board on which parts are mounted is discharged to the second transfer 50 by control of the controller 61 and the printed circuit board loaded on the first transfer 20 can be carried to the first conveyer 30.

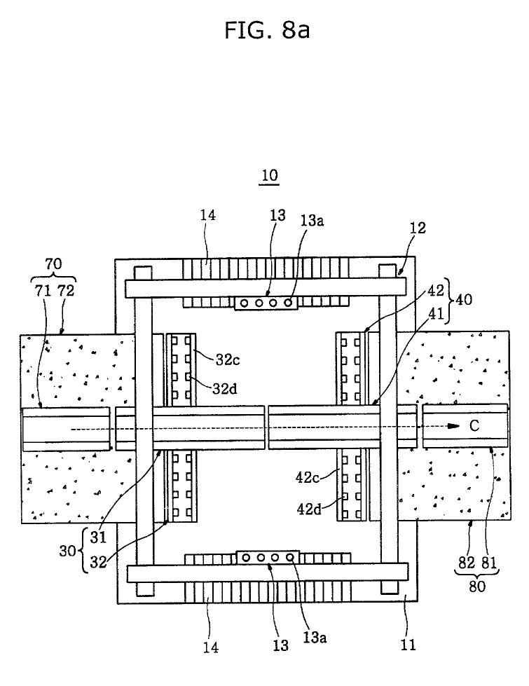

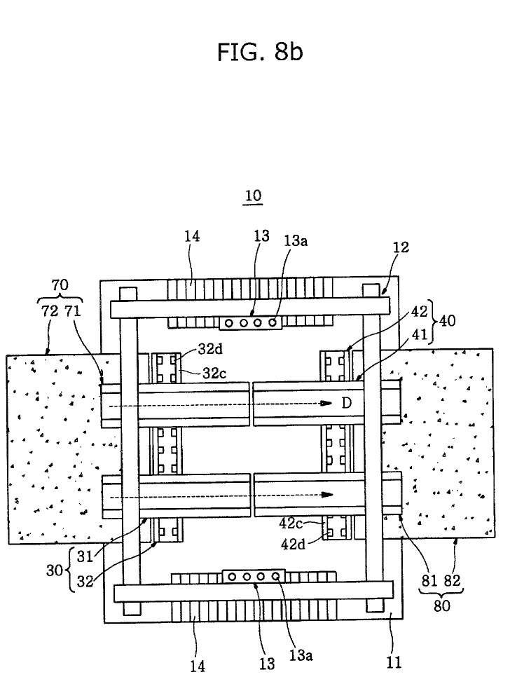

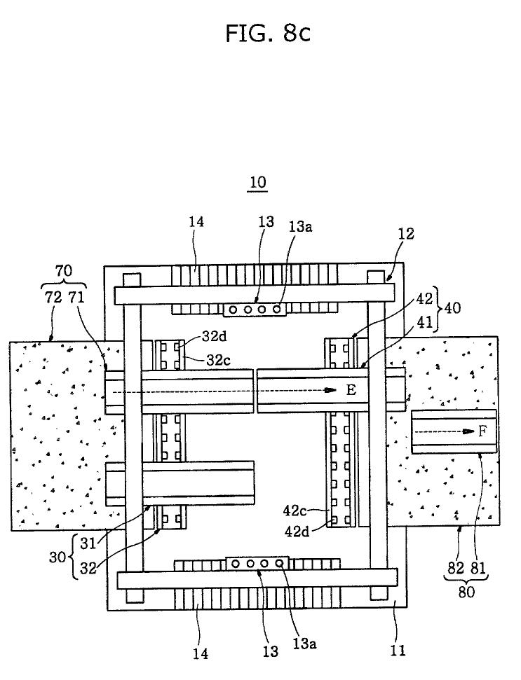

Another part surface mounting method will now be described with reference to the accompanying drawings. FIGS. 8a through 8c are views illustrating the parts mounting method using the surface mounting device according to the second embodiment of the present invention. Firstly, the first plane motion transfer unit 70 and the second plane motion transfer unit 80 are moved in plane motion by control of the controller 61 and supplies or discharges the printed circuit board in the direction as shown in arrows C, D, E and F of FIGS. 8a through 8c.

A step of carrying the printed circuit board moved in plane motion in a predetermined direction and loaded on the first plane motion transfer unit 70 to the first conveyer unit 30 or the second plane motion transfer unit 40 by control of the controller 61 in turns at a predetermined time interval is performed. Here, the first plane motion transfer unit 70 is moved to one end of the first conveyer unit 30 by control of the controller 61 to supply the printed circuit board to the first conveyer unit 30, and after a predetermined time, is moved to one end of the second conveyer unit 40 to supply the printed circuit board to the second conveyer unit 40. In addition, the printed circuit board can be supplied in the reverse order.

When the printed circuit board is carried to the first conveyer unit 30 or the second conveyer unit 40 at a predetermined time interval, a step of mounting parts on the carried printed circuit board by control of the controller 61 is performed. When the first conveyer unit 30 or the second conveyer unit 40 has finished the mounting of parts on the printed circuit board, a step of discharging the printed circuit board on which parts have been mounted to the second plane motion transfer unit 80 moved in plane motion in a predetermined direction by control of the controller 61 is performed. Here, when the mounting of parts on the printed circuit board is finished, the second plane motion transfer unit 80 is moved to the other end of the first conveyer unit 30 by control of the controller 61 for thereby discharging the printed circuit board on which parts have been mounted. When the discharging is finished, the second plane motion transfer unit 80 is moved to the other end of the second conveyer unit 40 for thereby receiving the printed circuit board on which parts have been mounted from the second conveyer unit 40 and loading the same. In addition, the printed circuit board can be discharged in the reverse order.

As seen from above, in the surface mounting device, the printed circuit board is carried by dividing a conveyer into a plurality of conveyers and then moving each of them horizontally or moving in plane motion in a predetermined direction a plurality of transfer units for supplying the printed circuit board to the plurality of transfer units or loading the discharged printed circuit board, for thereby eliminating a feed delay of the printed circuit board caused by the operation of mounting parts on the printed circuit board, improving the feed speed of the printed circuit board, and accordingly enhancing the speed of mounting parts.

What is claimed is:

1. A surface mounting device comprising:
a plurality of transfers being moved in the X and Y axis directions by an X-Y gantry installed on a base frame and supplying a printed circuit board for mounting parts or loading a discharged printed circuit by a head unit for sucking parts supplied from a parts supply unit and mounting the sucked parts on a printed circuit board; and
a plurality of conveyers and being installed to be moved horizontally in a predetermined direction at a predetermined position on the base frame and carrying the printed circuit board supplied from the plurality of transfers to a parts mounting work position and discharging the same to the plurality of transfers when the mounting of the parts is finished.

2. The surface mounting device of claim 1, wherein the plurality of transfers comprises a first transfer installed at one end of the base frame at which the plurality of conveyer are installed to be moved horizontally in a predetermined direction and supplies the printed circuit board to the plurality of conveyer units; and
a second transfer installed at the other end of the base frame at which the plurality of conveyer units are installed to be moved horizontally in a predetermined direction and loads the printed circuit board discharged from the plurality of conveyer units to the outside of the surface mounting device.

3. The surface mounting device of claim 2, wherein the first and second transfers comprise transfer guide frames for guiding the printed circuit board;
a plurality of transfer rollers installed at a predetermined interval from each other at side walls of the transfer guide frames and rotated by receiving the rotation force generated from the rotating motor for carrying the printed circuit board; and
belt members installed between the plurality of transfer rollers and driven by the rotation of the plurality of transfer rollers, for thereby carrying or loading the printed circuit board.

4. The surface mounting device of claim 1 or 2, wherein the plurality of conveyers comprise a first conveyer unit installed to be moved horizontally in a predetermined direction at a predetermined position of the base frame, for thereby carrying the printed circuit board supplied from the first transfer; and
a second conveyer unit installed to be moved horizontally in a predetermined direction at a predetermined position of the base frame, for thereby discharging the printed circuit board carried from the first conveyer unit to the second transfer.

5. The surface mounting device of claim 4, wherein the first conveyer unit comprises a first conveyer for carrying the printed circuit board supplied from the first transfer; and
a first horizontal driving unit installed on the bottom of the first conveyer and at a predetermined position of the base frame for thereby moving horizontally the first conveyer in a predetermined direction.

6. The surface mounting device of claim 4, wherein the second conveyer unit comprises a second conveyer for discharging the printed circuit board carried from the first conveyer; and
a second horizontal driving unit installed on the bottom of the first conveyer and at a predetermined position of the base frame for thereby moving horizontally the second conveyer in a predetermined direction.

7. The surface mounting device of claim 5 or 6, wherein the first and second conveyers each comprises conveyer guide frames for guiding each printed circuit board;
conveyer width adjusting rollers installed at a predetermined position of the conveyer guide frames and for guiding the conveyer guide frames when adjusting the width of the conveyer guide frames according to the width of the printed circuit board;
conveyer lifting members installed on the inside of the conveyer guide frames for mounting the parts to the printed circuit board or discharging the parts; and
first conveyer driving units installed at an inner sidewall of the first conveyer guide frames for carrying the printed circuit board.

8. The surface mounting device of claim 5 or 6, wherein the first and second horizontal driving units are any one among a ball screw driving device, a timing belt driving device, and a linear motor.

9. The surface mounting device of claim 8, wherein the linear motor is any one between a coil mover linear motor and a permanent magnet mover linear motor.

10. A surface mounting device comprising:
a plurality of plane motion transfer units being moved in the X and Y axis directions by an X-Y gantry installed on a base frame and loading a printed circuit board moved in plane motion in a predetermine direction in order to supply or discharge the printed circuit board for mounting parts by a head unit for sucking parts supplied from a parts supply unit and mounting the sucked parts on the printed circuit board; and
a plurality of conveyer units being installed to be moved horizontally in a predetermined direction at a predetermined position of the base frame and carrying the printed circuit board supplied from the plurality of plane motion transfer units to a parts mounting work position and discharging the same to the plurality of plane motion transfer units when the mounting of the parts is finished.

11. The surface mounting device of claim 10, wherein the plurality of plane motion transfer units comprise a first plane motion transfer unit for supplying the printed circuit board to the plurality of conveyer units in plane motion in a predetermined direction; and
a second plane motion transfer unit for loading the printed circuit board discharged from the plurality of conveyer units in plane motion in a predetermined direction.

12. The surface mounting device of claim 11, wherein the first plane motion transfer unit comprises a first plane motion transfer for carrying the printed circuit board; and
a first plane driving device for moving the first plane motion transfer in plane motion in a predetermined direction.

13. The surface mounting device of claim 11, wherein the second plane motion transfer unit comprises a second plane motion transfer for carrying the printed circuit board; and
a second plane driving device for moving the first plane motion transfer in plane motion in a predetermined direction.

14. The surface mounting device of claim 12 or 13, wherein the first and second transfers comprise transfer guide frames for guiding the printed circuit board;
a plurality of transfer rollers installed at a predetermined interval from each other at side walls of the transfer guide frames and rotated by receiving the rotation force generated from the rotating motor for carrying the printed circuit board; and
belt members installed between the plurality of transfer rollers and driven by the rotation of the plurality of transfer rollers, for thereby carrying or loading the printed circuit board.

15. The surface mounting device of claim 12 or 13, wherein the first and second plane driving devices are a plane motor, respectively.

16. The surface mounting device of claim 10, wherein the plurality of conveyers comprise a first conveyer unit installed to be moved horizontally in a predetermined direction at a predetermined position of the base frame, for thereby carrying the printed circuit board supplied from the first transfer; and
a second conveyer unit installed to be moved horizontally in a predetermined direction at a predetermined position of the base frame, for thereby discharging the printed circuit board carried from the first conveyer unit to the second transfer.

17. The surface mounting device of claim 16, wherein the first conveyer unit comprises a first conveyer for carrying the printed circuit board supplied from the first transfer; and
a first horizontal driving unit installed on the bottom of the first conveyer and at a predetermined position of the base frame for thereby moving horizontally the first conveyer in a predetermined direction.

18. The surface mounting device of claim 16, wherein the second conveyer unit comprises a second conveyer for discharging the printed circuit board carried from the first conveyer; and
a second horizontal driving unit installed on the bottom of the first conveyer and at a predetermined position of the base frame for thereby moving horizontally the second conveyer in a predetermined direction.

19. The surface mounting device of claim 17 or 18, wherein the first and second conveyers each comprises conveyer guide frames for guiding each printed circuit board;
conveyer width adjusting rollers installed at a predetermined position of the conveyer guide frames and for guiding the conveyer guide frames when adjusting the width of the conveyer guide frames according to the width of the printed circuit board;
conveyer lifting members installed on the inside of the conveyer guide frames for mounting the parts to the printed circuit board or discharging the parts; and
first conveyer driving units installed at an inner sidewall of the first conveyer guide frames for carrying the printed circuit board.

20. The surface mounting device of claim 17 or 18, wherein the first and second horizontal driving units are any one among a ball screw driving device, a timing belt driving device, and a linear motor.

21. The surface mounting device of claim 20, wherein the linear motor is any one between a coil mover linear motor and a permanent magnet mover linear motor.

22. A surface mounting method comprising the steps of:
carrying a printed circuit board loaded on the first transfer to a first conveyer unit by control of a controller;
carrying the carried printed circuit board to a second conveyer unit by control of the controller when the printed circuit board is carried to the first conveyer unit;
mounting parts on the printed circuit board carried to the second conveyer unit by control of the controller and carrying the printed circuit board loaded on the first transfer to the first conveyer unit when the printed circuit board is carried to the second conveyer unit; and
discharging the printed circuit board on which parts have been mounted to the second transfer by control of the controller and carrying the printed circuit board carried to the first conveyer unit when the mounting of parts on the printed circuit board in the second conveyer unit is finished.

23. The surface mounting method of claim 22, wherein in the above step of carrying the printed circuit board to the second conveyer unit by the first conveyer unit, it is also possible to mount parts on the printed circuit board carried to the first conveyer unit by control of the controller and then carry the printed circuit board to the second conveyer unit.

24. The surface mounting method of claim 22, wherein in the step of mounting parts on the printed circuit board carried to the second conveyer unit by control of the controller and carrying the printed circuit board loaded on the first transfer to the first conveyer unit when the printed circuit board is carried to the second conveyer unit, the printed circuit board on which parts are mounted is discharged to the second transfer by control of the controller and the printed circuit board loaded on the first transfer can be carried to the first conveyer when parts have been mounted on the printed circuit board carried to the second conveyer unit.

25. A surface mounting method comprising the steps of:
carrying the printed circuit board moved in plane motion by control of a controller in a predetermined direction and loaded on the first plane motion transfer unit to the first conveyer unit or the second plane motion transfer unit by control of the controller in turns at a predetermined time interval;
mounting parts on the carried printed circuit board by control of the controller when the printed circuit board is carried to the first conveyer unit or the second conveyer unit at a predetermined time interval; and
discharging the printed circuit board on which parts have been mounted to the second plane motion transfer unit moved in plane motion in a predetermined direction by control of the controller is performed when the first conveyer unit or the second conveyer unit has finished the mounting of parts on the printed circuit board.

26. The surface mounting method of claim 25, wherein in the step of carrying the printed circuit board loaded on the first plane motion transfer unit to the first conveyer unit or the second plane motion transfer unit by control of the controller in turns at a predetermined time interval, the first plane motion transfer unit is moved to one end of the first conveyer unit by control of the controller to supply the printed circuit board to the first conveyer unit, and thereafter is moved to one end of the second conveyer unit to supply the printed circuit board to the second conveyer unit.

27. The surface mounting method of claim 25, wherein when the first plane motion transfer unit is moved to one end of the first conveyer unit by control of the controller to supply the printed circuit board to the first conveyer unit, and after a predetermined time, is moved to one end of the second conveyer unit to supply the printed circuit board to the second conveyer unit, the first plane motion transfer unit is moved to one end of the second conveyer unit by control of the controller to supply the printed circuit board to the second conveyer unit, and thereafter is moved to one end of the first conveyer unit to supply the printed circuit board to the first conveyer unit.

28. The surface mounting method of claim 25, wherein in the step of discharging the printed circuit board on which parts have been mounted to the second plane motion transfer unit moved in plane motion in a predetermined direction by control of the controller, when the mounting of parts on the printed circuit board is finished, the second plane motion transfer unit is moved to the other end of the first conveyer unit by control of the controller for thereby discharging the printed circuit board on which parts have been mounted and when the discharging is finished, the second plane motion transfer unit is moved to the other end of the second conveyer unit for thereby receiving the printed circuit board on which parts have been mounted from the second conveyer unit and loading the same.

29. The surface mounting method of claim 25, wherein when the mounting of parts on the printed circuit board is finished, the second plane motion transfer unit is moved to the other end of the first conveyer unit by control of the controller for thereby discharging the printed circuit board on which parts have been mounted and when the discharging is finished, the second plane motion transfer unit is moved to the other end of the second conveyer unit for thereby receiving the printed circuit board on which parts have been mounted from the second conveyer unit and loading the same, the second plane motion transfer unit is moved to the other end of the second conveyer unit by control of the controller for thereby discharging the printed circuit board on which parts have been mounted and when the discharging is finished, the second plane motion transfer unit is moved to the other end of the first conveyer unit for thereby receiving the printed circuit board on which parts have been mounted from the first conveyer unit and loading the same.
